(19) United States
(12) Patent Application Publication
(10) Pub. No.: US 2005/0178947 A1
(43) Pub. Date: Aug. 18, 2005

(54) System and method for object identification

(75) Inventors: Kouji Sasaki, Higashihiroshima (JP); Hidenori Tatsumi, Higashihiroshima (JP); Masahiro Horie, Kuga-gun (JP); Masaaki Morioka, Higashihiroshima (JP)

Correspondence Address: WENDEROTH, LIND & PONACK, L.L.P., 2033 K STREET N. W., SUITE 800, WASHINGTON, DC, 20006-1021, US

(73) Assignee: Matsushita Electric Industrial Co., Ltd., Osaka (JP)

(21) Appl. No.: 10/512,846

(22) PCT Filed: May 10, 2004
(86) PCT No.: PCT/JP04/06577

(30) Foreign Application Priority Data
May 16, 2003 (JP) 2003-139483

(51) Int. Cl. H01L 27/00

(52) U.S. Cl. 250/208.1

(57) ABSTRACT

In an object identification system, phototransmitters 100 which are assigned to at least one object send out invisible light having rectilinearity. A control device 200, which is placed near an object, instructs the phototransmitter 100 that is assigned to an object selected by a user to transmit information for uniquely identifying an object or an imaging device. In response to this instruction, the phototransmitter 100 sends out invisible light having first information superposed thereon. An imaging device 300 to be carried around by the user includes, in order to take in an image: a storage section for storing second information for uniquely identifying the object selected by the user or the imaging device itself; a photoreceiving section for receiving invisible light which is sent out from the phototransmitter 100 and extracting first information superposed on the received light; a determination section for determining whether or not to take in an image based on the first information which is sent from the photoreceiving section and the second information which is stored in the storage section; and a photoreceiving device. The imaging device 300 further includes: an image input section for taking in an image representing the surroundings of an object to which a phototransmitter that is currently sending out invisible light is assigned if the determination section has determined to take in an image; and a displaying section for displaying the image representing the surroundings of the object which has been taken in by the image input section. The image input section incorporates a photoreceiving device which has a sensitive range including the wavelength of the invisible light, so that the displaying section can display the object and the light emission by the phototransmitter which is assigned to the object.

### TECHNICAL FIELD

The present invention relates to a system and method for object identification, and more particularly to a system and method for object identification which notifies a place in which an object targeted by the user is located.

### BACKGROUND ART

In recent years, digital equipments which are complete with an imaging function and which can be carried by a user on the go (hereinafter referred to as “imaging device”) are gaining prevalence. Typical examples of such an imaging device are: a digital still camera, a cellular phone equipped with a camera, or a PDA (Personal Digital Assistant) which incorporates a camera module. Such a mobile device may be utilized by a user in various situations. For example, a user may bring an image which has been casually taken with a mobile device into a personal computer, in order to make an electronic album or send it as attached to an e-mail. In business situations, it is frequently practiced to paste or attach an electronic image which has been taken with a digital still camera to a report or a presentation material.

At an exhibition, for example, it has become commonplace for a user to take pictures of exhibited items by using an imaging device, and show such electronic images to people who did not go to the exhibition for explanation. However, while such usage may make it possible to take a picture of an exhibited item of interest, it is still necessary for the user to obtain related information, such as the features and specifications of the exhibited item, from a pamphlet which is prepared at the place or take notes of information which is offered by a person who is in charge of explanation. In other words, there is a problem in that, for a given exhibited item of interest, the user cannot concurrently obtain an image and related information thereof.

In order to solve the above problem, an imaging information inputting system as follows has been proposed. According to this imaging information inputting system, a transmitter for transmitting related information of an object to be pictured is placed near the object to be pictured. A camera, employed as an imaging device, acquires related information which is transmitted from the transmitter, and records the acquired related information and an image of the object to be pictured, such that the acquired related information and the image are recorded in association with each other.

As another example of background art, a system (hereinafter referred to as a “book/magazine information distribution system”) is known in which, as a user approaches a bookshelf in a book store, review data concerning well-selling books or magazines, for example, is automatically delivered to a mobile terminal device such as a cellular phone or a notebook-type personal computer.

### DISCLOSURE OF THE INVENTION

However, the above-described imaging information inputting system has a problem in that, while the user is able to automatically acquire related information, the user still needs to look for, on his or her own, an object which the user desires to take a picture of.

Meanwhile, the above-described book/magazine information distribution system has a problem in that, while the mobile terminal device is able to display whether a book or magazine of interest exists or not, or which corner it can be found in, the user still cannot pinpoint where exactly the desired book or magazine can be found.

Therefore an objective of the present invention is to provide a system and method for object identification which enables a user to find an object with certainty and ease.

To achieve the above objective, a first aspect of the present invention is directed to an imaging device which, in cooperation with a phototransmitter being placed near at least one object and capable of sending out invisible light having rectilinearity, identifies the object by using a photoreceiving device having a sensitive range including a wavelength of the invisible light, the invisible light having superposed thereon first information for uniquely identifying the object or the imaging device, the imaging device comprising: a storage section operable to store second information for uniquely identifying an object selected by a user or the imaging device itself; a photoreceiving section operable to receive the invisible light sent out from the phototransmitter, and extract the first information superposed on the received light; a determination section operable to determine whether or not to take in an image based on the first information sent from the photoreceiving section and the second information stored in the storage section; an image input section operable to take in an image representing light emission by the phototransmitter and surroundings thereof if the determination section has determined to take in an image; and a displaying section operable to display the image representing light emission by the phototransmitter and the surroundings thereof which has been taken in by the image input section.

A synchronization signal for controlling the imaging device may be further superposed on the invisible light, and the image input section may store, in accordance with the synchronization signal, the image which has been taken in to a frame memory.

The imaging device may further comprise a communication section operable to transmit the first information for identifying the object selected by the user or the imaging device itself to, via a network, a control device which is placed near the object for controlling the light emission by the phototransmitter, the control device instructing the phototransmitter to transmit the first information which is sent from the communication section.

The phototransmitter may include a plurality of light-emitting devices, such that related information concerning the object is output through light emission by some of the plurality of light-emitting devices, and the displaying section may further display the related information concerning the object.

Related information concerning the object may be further superposed on the invisible light; the photoreceiving section may extract the related information from the invisible light which is sent from the phototransmitter; the imaging device may further comprise an image processing section operable to merge the related information which has been extracted by the photoreceiving section with the image which has been taken in by the image input section; and the displaying section may display the image having the related information merged therewith by the image processing section.

The imaging device may further comprise: a wireless communication section operable to receive area information from a wireless communication device which is placed near the object for transmitting the area information indicating that the object is near; and an output section operable to output the area information received by the wireless communication section.

A second aspect of the present invention is directed to an object identification method by which, in cooperation with a phototransmitter being placed near at least one object and capable of sending out invisible light having rectilinearity, an imaging device identifies the object by using a photoreceiving device having a sensitive range including a wavelength of the invisible light, the invisible light having superposed thereon first information for uniquely identifying the object or the imaging device, the object identification method comprising: a storage step of storing second information for uniquely identifying an object selected by a user or the imaging device itself; a photoreceiving step of receiving the invisible light sent out from the phototransmitter, and extract the first information superposed on the received light; a determination step of determining whether or not to take in an image based on the first information sent from the photoreceiving step and the second information stored in the storage step; an image input step of taking in an image representing light emission by the phototransmitter and surroundings thereof if the determination step has determined to take in an image; and a displaying step of displaying the image representing light emission by the phototransmitter and the surroundings thereof which has been taken in by the image input step.

A third aspect of the present invention is directed to a computer program for use in an imaging device which, in cooperation with a phototransmitter being placed near at least one object and capable of sending out invisible light having rectilinearity, identifies the object by using a photoreceiving device having a sensitive range including a wavelength of the invisible light, the invisible light having superposed thereon first information for uniquely identifying the object or the imaging device, the computer program comprising: a storage step of storing second information for uniquely identifying an object selected by a user or the imaging device itself; an information acquisition step of extracting the first information superposed on the invisible light sent out from the phototransmitter and received by the imaging device; a determination step of determining whether or not to take in an image based on the first information extracted in the information acquisition step and the second information stored in the storage step; an image acquisition step of taking in an image representing light emission by the phototransmitter and surroundings thereof if the determination step has determined to take in an image; and a transfer step of transferring, to a display section comprised by the imaging device, the image representing light emission by the phototransmitter and the surroundings thereof which has been taken in by the image acquisition step.

According to the first to third aspects above, a phototransmitter for emitting invisible light having rectilinearity is assigned to an object. Each phototransmitter emits invisible light having first information superposed thereon for enabling the identification of an object or an imaging device. The imaging device determines whether or not to take in an image, based on the first information superposed on the invisible light. If an affirmative determination is made, the imaging device takes in an image. Since the photoreceiving device has a sensitive range which includes the wavelength of the invisible light, the displaying section will display the emission of the phototransmitter. As a result, the user can locate an object of interest, with certainty and ease.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic diagram illustrating a schematic diagram structure of an object identification system according to a first embodiment of the present invention.

FIG. 2 is a block diagram illustrating a detailed structure of the object identification system shown in FIG. 1.

FIG. 3 is a sequence chart illustrating a communication procedure of the object identification system shown in FIG. 2.

FIG. 4 is a block diagram illustrating a detailed structure of an object identification system according to a second embodiment of the present invention.

FIG. 5 is a sequence chart illustrating a communication procedure of the object identification system shown in FIG. 4.

FIG. 6 is a block diagram illustrating a detailed structure of an object identification system according to a third embodiment of the present invention.

FIG. 7 is a sequence chart illustrating a communication procedure of the object identification system shown in FIG. 4.

FIG. 8 is a diagram illustrating emission timing of the phototransmitter 100 shown in FIG. 6.

FIG. 9 is a block diagram illustrating a detailed structure of an object identification system according to a fourth embodiment of the present invention.

FIG. 10 is a sequence chart illustrating a communication procedure of the object identification system shown in FIG. 9.

FIG. 11 is a block diagram illustrating a detailed structure of an object identification system according to a fifth embodiment of the present invention.

FIG. 12 is a sequence chart illustrating a communication procedure of the object identification system shown in FIG. 11.

FIG. 13 is a flowchart illustrating a first variant of the processing by the imaging device 300.

FIG. 14 is a schematic diagram exemplifying an image to be displayed by the image displaying section 307 through the process shown in FIG. 13.

FIG. 15 is a flowchart illustrating a second variant of the processing by the imaging device 300.

FIG. 16 is a block diagram illustrating an overall structure of an object identification system 1 according to a sixth embodiment of the present invention.

FIG. 17 is a schematic diagram illustrating an exemplary installation of the object identification system 1 shown in FIG. 16.

FIG. 18 is a block diagram illustrating a detailed structure of a control device 13 shown in FIG. 16.

FIG. 19 is a schematic diagram exemplifying a structure of an object database DB to be stored in an object information storing section 131 shown in FIG. 16.

FIG. 20 is a schematic diagram exemplifying menu information which is distributed by the information distribution device 14 shown in FIG. 16.

FIG. 21 is a block diagram illustrating a detailed structure of an imaging device 15 shown in FIG. 16.

FIG. 22A and FIG. 22B are a former half and a latter half of a sequence chart illustrating a procedure of communications between the respective elements shown in FIG. 16.

### BEST MODE FOR CARRYING OUT THE INVENTION

### First Embodiment

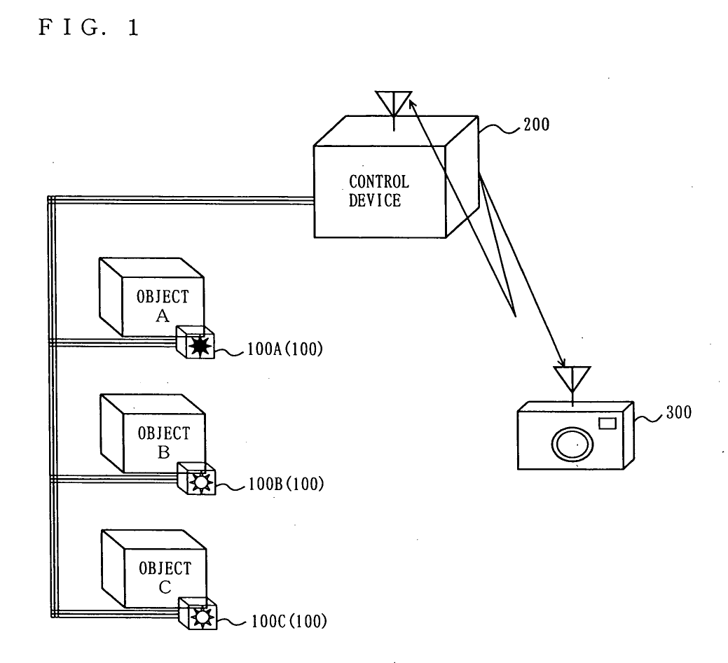

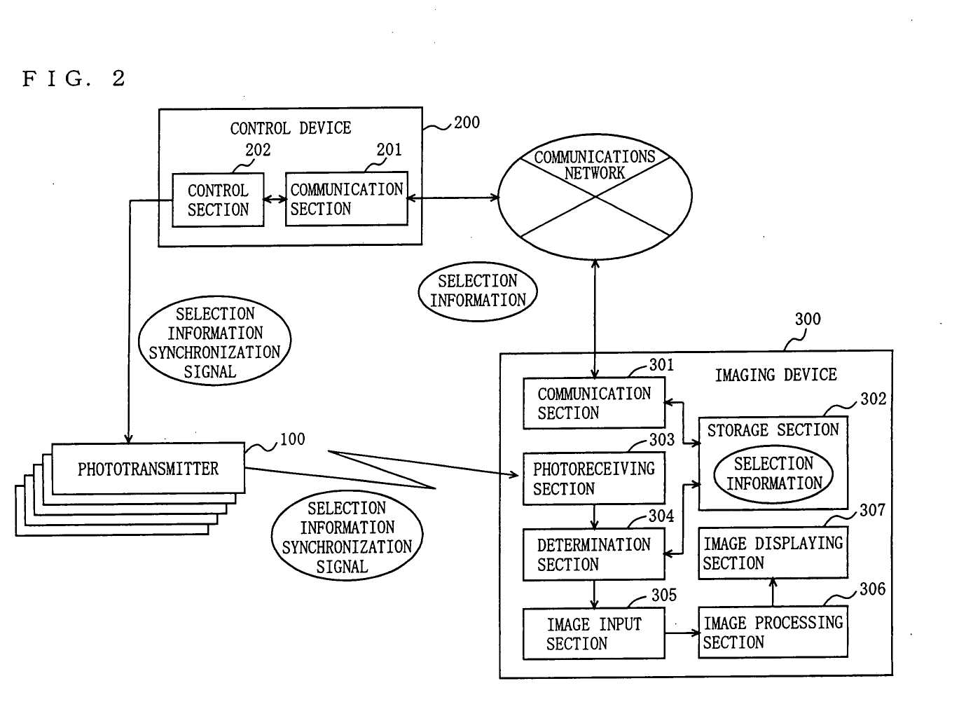

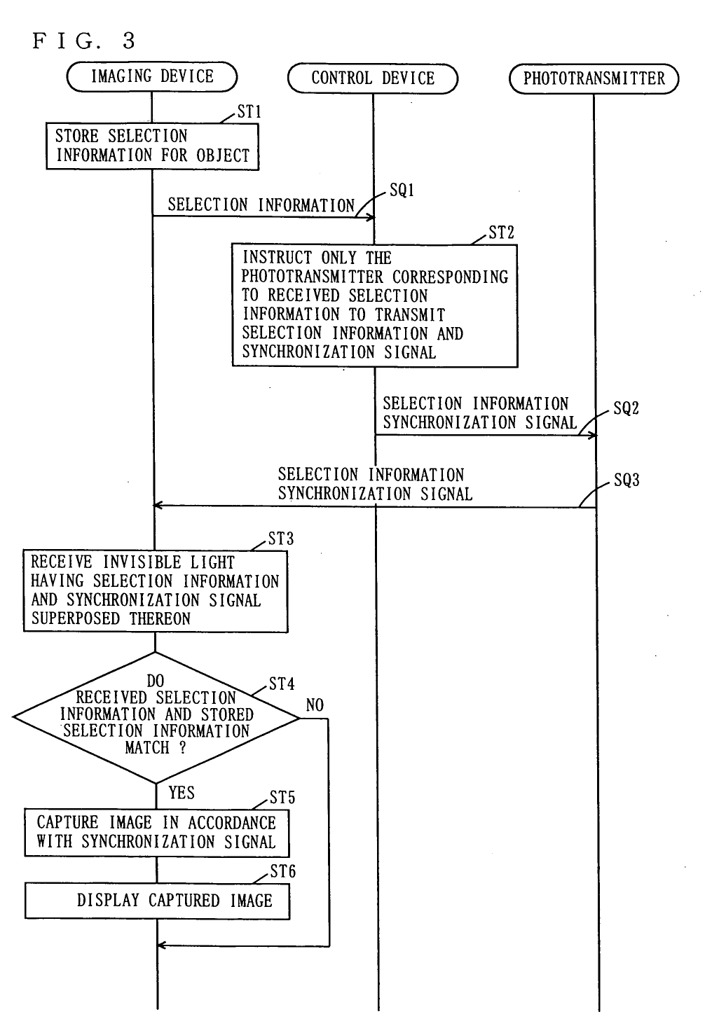

An object identification system and an object identification method according to a first embodiment of the present invention will be described with reference to the schematic diagram of FIG. 1, the block diagram of FIG. 2, and the sequence chart of FIG. 3.

As shown in FIG. 1 and FIG. 2, the present object identification system comprises: phototransmitters 100 (100A, 100B, and 100C) provided corresponding to one object or two or more objects (three objects A, B, and C are exemplified in FIG. 1); a control device 200 for controlling each phototransmitter 100; and an imaging device 300 which is capable of establishing a communication link with the control device 200 via a communications network such as a public circuit.

A typical example of the control device 200 is a personal computer. A typical example of the imaging device 300 is a digital camera, or a cellular phone equipped with a camera. The control device 200 and the imaging device 300 perform wired communications or wireless communications with each other. Examples of the objects are books or magazines which are placed in a bookshelf of a book store, or exhibited items which are on display at an exhibition, although not particularly limited thereto.

The phototransmitters 100 (100A to 100C) generate invisible light under the control of the control device 200. Invisible light contains wavelengths which are not perceived by the human eyes, but which fall within a sensitive range of a photoreceiving device (not shown), such as a CCD (Charge Coupled Device), that is comprised by the imaging device 300. A typical example of such invisible light is infrared radiation. Other types of invisible light exist besides infrared radiation, such as ultraviolet rays. However, preferable invisible light is infrared radiation because it facilitates applications for data communications. It is still more preferable that the invisible light has rectilinearity. Although infrared radiation spreads out to a certain degree, infrared radiation far excels in rectilinearity as compared to radiowaves, for example. Due to such rectilinearity, even if the phototransmitters 100 are provided for a large number of objects, the infrared radiation which is emitted from a given phototransmitter 101 is not susceptible to the interference of the infrared radiation from any other phototransmitter 101.

The control device 200 includes a communication section 201 and a control section 202. Furthermore, the imaging device 300 includes a communication section 301, a storage section 302, a photoreceiving section 303, a capture determination section 304, an image input section 305, an image processing section 306, and an image displaying section 307.

Via a communications network, the communication section 301 of the imaging device 300 transmits selection information for selecting an object to the control device 200.

The storage section 302 stores selection information for selecting an object.

The photoreceiving section 303 receives the invisible light which has been sent from the phototransmitter 100, with the synchronization signal and the selection information being superposed on the invisible light.

The capture determination section 304 compares the selection information contained in the invisible light received by the photoreceiving section 303 against the selection information which is stored in the storage section 302, and determines whether they match or not.

If it is determined by the capture determination section 304 that the two pieces of selection information match, the image input section 305 takes in an image by using an optical system and a photoreceiving device (neither of which is shown) composing the image input section 305, and passes the image to the image processing section 306. The photoreceiving device has a sensitive range which includes the wavelength of the invisible light emitted by the phototransmitters 100.

The image processing section 306 passes the image which has been sent from the image input section 305 to the image displaying section 307. At this time, the image processing section 306 preferably processes the image so that the emission by the phototransmitter 100 becomes more outstanding. Note that the function of the image processing section 306 may alternatively be imparted to the image input section 305 or the image displaying section 307.

The image displaying section 307 displays the image which has been sent from the image processing section 306. Since the wavelength of the invisible light falls within the sensitive range of the image input section 305, the user is able to visually perceive the emission by the phototransmitter 100 on the displayed image.

In the control device 200, the communication section 201 receives the selection information for selecting an object which has been transmitted from the communication section 301 of the imaging device 300. The control section 202 instructs only the phototransmitter 100 which is provided for an object that is specified by the received selection information to transmit a synchronization signal and selection information. For example, if the received selection information is for selecting the object A, the control section 202 instructs only the phototransmitter 100A, corresponding to the object A, to transmit a synchronization signal and selection information.

In accordance with an instruction from the control device 200, the phototransmitter 100 generates and sends out invisible light having a synchronization signal and selection information superposed thereon. In other words, the phototransmitter 100 emits light in response to an instruction from the control device 200. FIG. 1 illustrates an exemplary case where only the phototransmitter 100A is emitting invisible light.

Next, the object identification method will be described with reference to the sequence chart of FIG. 3.

First, to the imaging device 300, the user inputs information concerning a target object (e.g., the object A), via key operations or via the communications network from the control device 200. The object information which has been input is stored to the storage section 302 of the imaging device 300 as selection information for specifying the object (step ST1).

Next, the imaging device 300 reads the selection information which is stored to the storage section 302, and transmits the selection information from the communication section 301 to the control device 200, via the communications network (sequence SQ1).

Next, upon receiving the signal from the imaging device 300, the control device 200 instructs only the phototransmitter 100 (e.g., 100A) which is assigned to an object (e.g., the object A) corresponding to the received selection information to transmit selection information and a capture synchronization signal (step ST2, sequence SQ2).

In response to the instruction from the control device 200, the phototransmitter 100 (e.g., 100A) sends out invisible light having selection information and a synchronization signal superposed thereon (sequence SQ3).

If the user brings the imaging device 300 near the object in this state, the photoreceiving section 303 of the imaging device 300 receives the invisible light which is being sent out from the phototransmitter 100 (e.g., 100A) (step ST3).

The capture determination section 304 of the imaging device 300 compares the selection information which is superposed on the received invisible light against the selection information which is previously stored in the storage section 302, and determines whether they match or not (step ST4).

If step ST4 determines YES, the image input section 305 takes in an image (step ST5). Preferably, the image input section 305 stores the image to an internal frame memory based on the synchronization signal which is sent together with the selection information. Such an image may be stored to a storage medium such as an SD card®, in accordance with the user's instruction. If step ST4 determines NO, the image input section 305 does not take in any image.

Thereafter, the image displaying section 307 receives the image which has been captured by the image input section 305 via the image processing section 306, and displays the image (step ST6).

Thus, according to the present embodiment, a captured image concerning the object (e.g., the object A) which is indicated in the selection information as desired by the user is automatically displayed on the image displaying section 307 of the imaging device 300. At this time, the emission of the phototransmitter 100 is also automatically displayed in the captured image, thus enabling the user to distinguish the object very clearly.

In the present embodiment, the invisible light in the form of infrared radiation performs three roles: a transmission medium of the synchronization signal, a transmission medium of the selection information, and object identification. Infrared radiation, which is used for control signal transmission and data communications in a remote control or IrDA, for example, is not perceived by the human eyes because it is not visible light. However, since infrared radiation falls within the sensitive range of the photoreceiving device comprised by the imaging device 300, the emission of the phototransmitter 100 can be observed by simply allowing the infrared radiation which has been received by the CCD to be displayed on the image displaying section 307. Since invisible light is used, the emission by the phototransmitter 100 is not visually perceived by anyone other than the user. Thus, people in the surrounding vicinity are less likely to be annoyed thereby.

### Second Embodiment

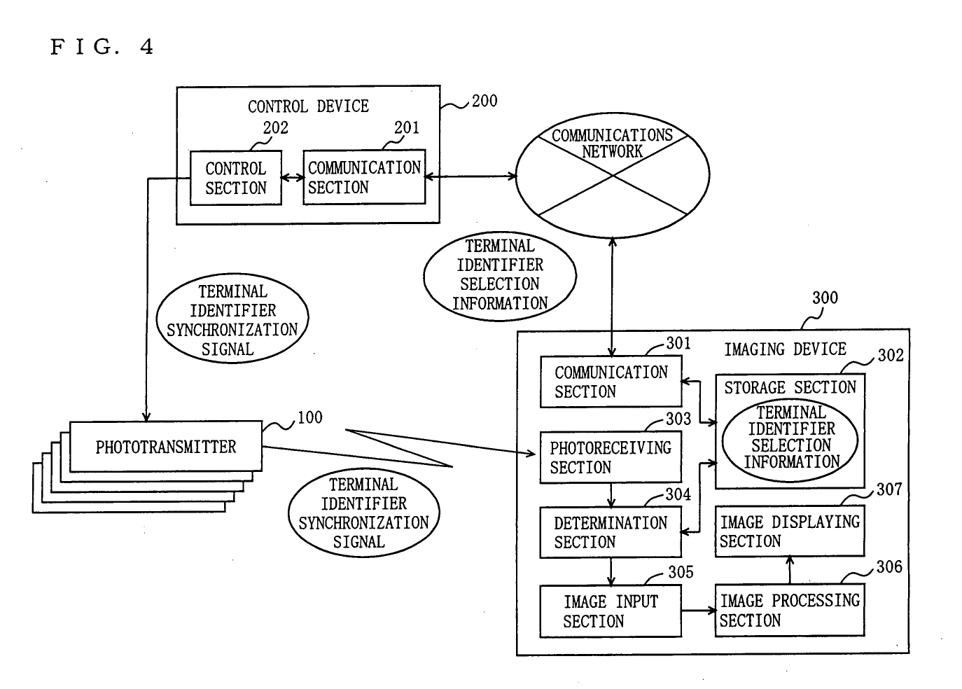

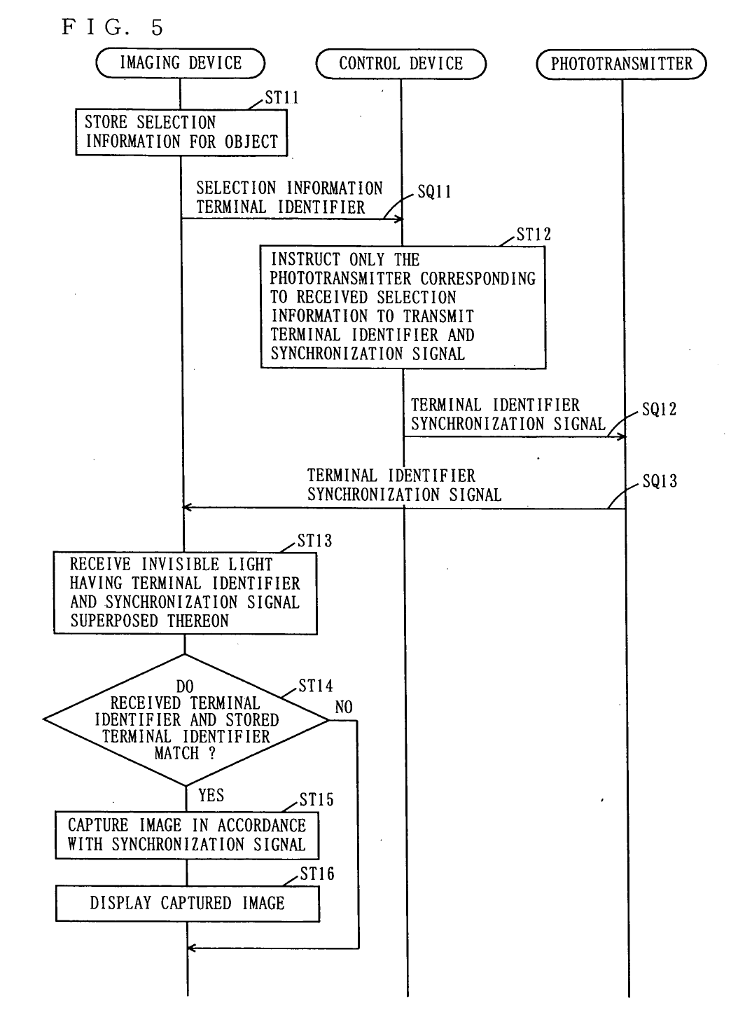

Next, an object identification system and an object identification method according to a second embodiment of the present invention will be described with reference to the block diagram of FIG. 4 and the sequence chart of FIG. 5. The present object identification system has the same construction as that described in the first embodiment except for the following aspects. Therefore, in FIG. 4, elements which correspond to those in FIG. 2 are indicated by the same reference numerals as those used therein. A difference between the two embodiments is that a terminal identifier which is unique to the imaging device 300 is transmitted and received within the object identification system.

In other words, in the imaging device 300, the communication section 301 transmits not only the aforementioned selection information, but also a terminal identifier to the control device 200, via a communications network.

The storage section 302 further stores the terminal identifier in addition to the aforementioned selection information.

The photoreceiving section 303 receives invisible light which is sent from the phototransmitter 100. Not only the aforementioned selection information, but also the terminal identifier is superposed on the invisible light.

The capture determination section 304 compares the terminal identifier contained in the invisible light received by the photoreceiving section 303 against the terminal identifier which is stored in the storage section 302, and determines whether they match or not.

If it is determined by the capture determination section 304 that the two pieces of selection information match, the image input section 305 takes in an image, and passes the image to the image processing section 306. As described earlier, the photoreceiving device composing the image input section 305 has a sensitive range which includes the wavelength of the invisible light.

As in the case of the first embodiment, the image processing section 306 performs necessary processing for the image which is sent from the image input section 305, and thereafter passes the processed image to the image displaying section 307.

As in the case of the first embodiment, the image displaying section 307 displays the image which has been sent from the image processing section 306.

In the control device 200, the communication section 201 receives the selection information and the terminal identifier which are transmitted from the communication section 301 of the imaging device 300. As in the case of the first embodiment, the control section 202 instructs only the phototransmitter 100 which is provided for an object that is specified by the received selection information to transmit a synchronization signal and the terminal identifier.

In accordance with an instruction from the control device 200, the phototransmitter 100 generates and sends out invisible light having a synchronization signal and the terminal identifier superposed thereon. In other words, the phototransmitter 100 emits light in response to an instruction from the control device 200.

Next, the object identification method will be described with reference to the sequence chart of FIG. 5.

First, as in the aforementioned step ST1, the user inputs information concerning a target object (e.g., the object A), via key operations or via the communications network from the control device 200. The object information which has been input is stored to the storage section 302 of the imaging device 300 as selection information (step ST11).

Moreover, as described above, the storage section 302 stores a terminal identifier which is unique to the imaging device 300. Next to step ST11, the imaging device 300 reads from the storage section 302 the selection information and the terminal identifier stored in the storage section 302, and thereafter transmit the selection information and the terminal identifier from the communication section 301 to the control device 200, via the communications network (sequence SQ11).

Upon receiving the signal from the imaging device 300, the control device 200 instructs only the phototransmitter 100 (e.g., 100A) which is assigned to an object (e.g., the object A) corresponding to the received selection information to transmit the terminal identifier and a synchronization signal (step ST12, sequence SQ12).

In response to the instruction from the control device 200, the phototransmitter 100 (e.g., 100A) sends out invisible light having the terminal identifier and a synchronization signal superposed thereon (sequence SQ13).

If the user brings the imaging device 300 near the object in this state, the photoreceiving section 303 of the imaging device 300 receives the invisible light which is being sent out from the phototransmitter 100 (e.g., 100A) (step ST13).

In the imaging device 300, the capture determination section 304 compares the terminal identifier which is superposed on the received invisible light against the terminal identifier which is previously stored in the storage section 302, and determines whether they match or not (step ST14).

If step ST14 determines YES, the image input section 305 takes in an image (step ST15). Preferably, the image input section 305 stores the image to an internal frame memory based on the synchronization signal which is sent together with the selection information. Such an image may be stored to a storage medium such as an SD card®, in accordance with the user's instruction. If step ST14 determines NO, the image input section 305 does not take in any image. Thereafter, the image displaying section 307 receives via the image processing section 306 the image which has been taken in by the image input section 305, and displays the image (step ST16).

As described above, according to the present embodiment, as in the case of the first embodiment, a captured image concerning the object (e.g., the object A) which is indicated in the selection information as desired by the user is automatically displayed on the image displaying section 307 of the imaging device 300. At this time, the emission of the phototransmitter 100 is also automatically displayed in the captured image, thus enabling the user to distinguish the object very clearly.

According to the second embodiment, the terminal identifier is superposed on the invisible light, thereby making it easier for a single imaging device 300 to distinguish and capture a plurality of objects.

### Third Embodiment

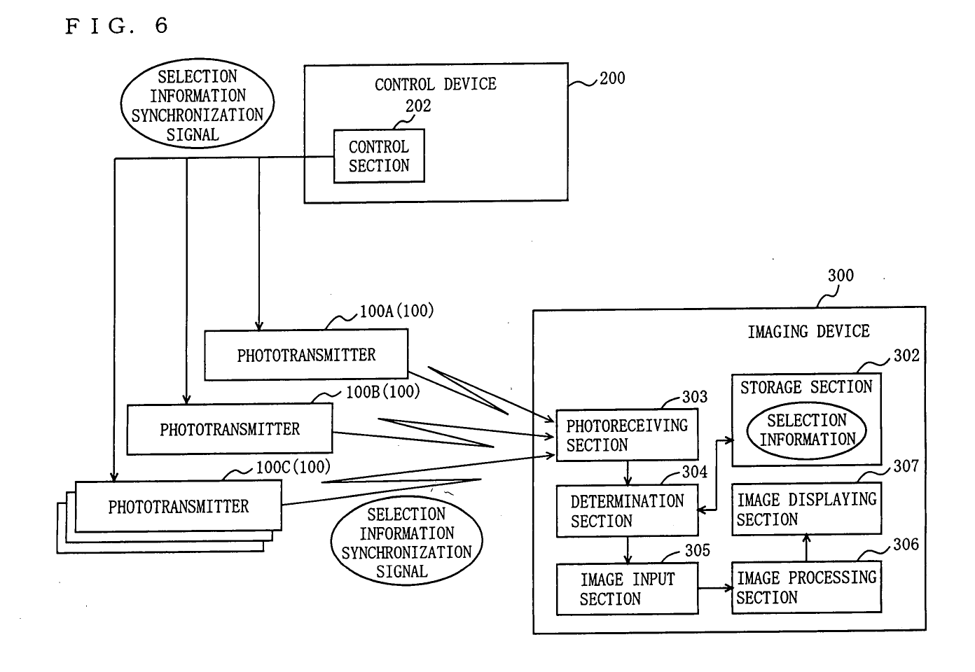

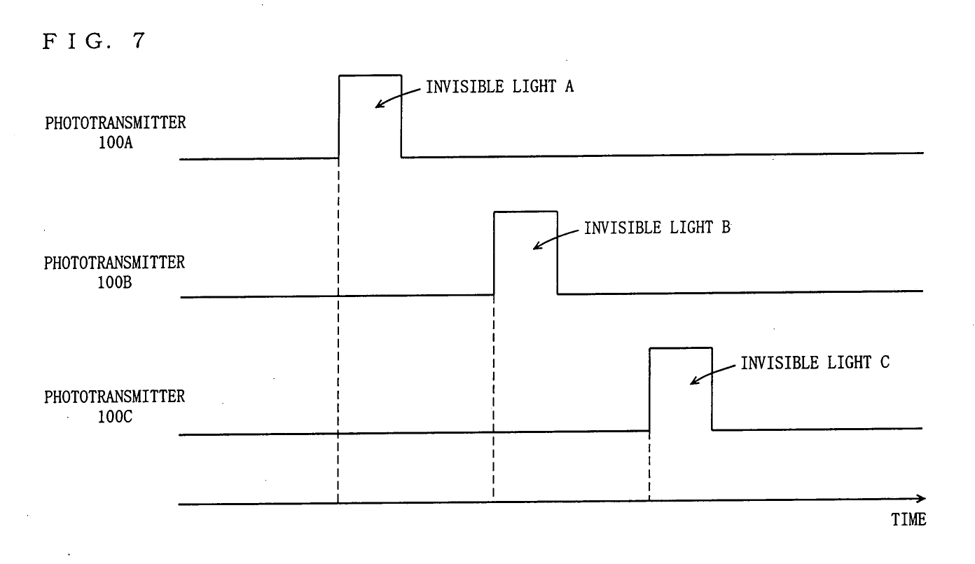

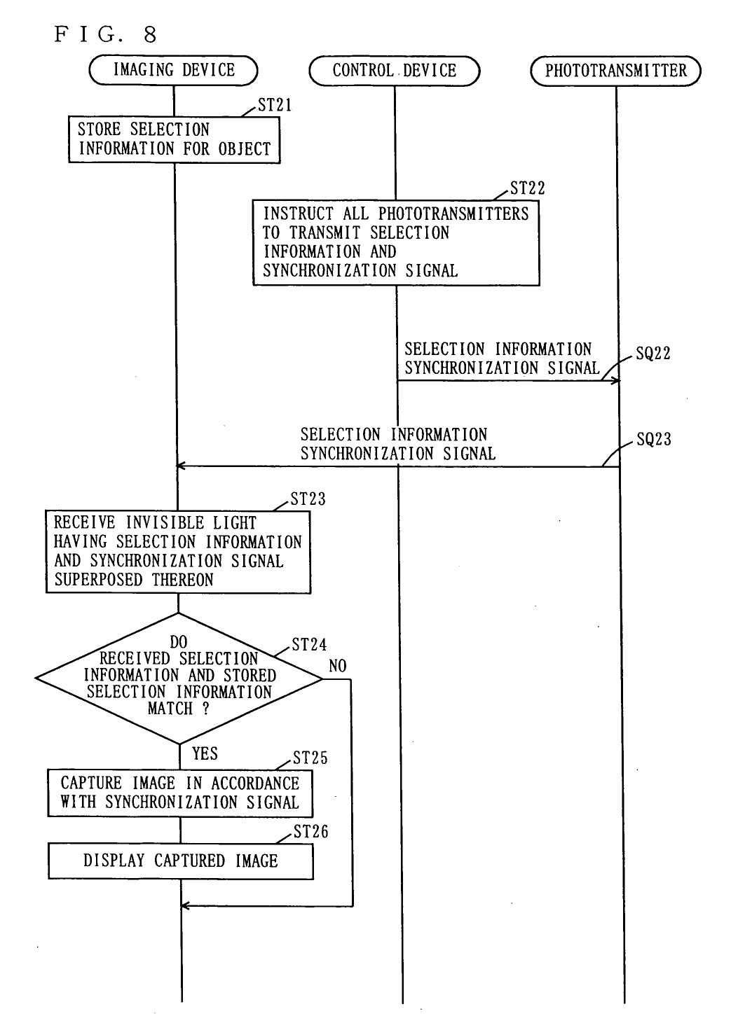

Next, an object identification system and an object identification method according to a third embodiment of the present invention will be described with reference to the block diagram of FIG. 6, the sequence chart of FIG. 7, and the timing chart of FIG. 8. The present object identification system has the same construction as that described in the first embodiment except for the following aspects. Therefore, in FIG. 6, elements which correspond to those in FIG. 2 are indicated by the same reference numerals as those used therein. A difference between the two embodiments is that the imaging device 300 lacks a communication section 301 and that the control device 200 lacks a communication section 201. Due to such structural differences, all phototransmitters 100 are to transmit invisible light having selection information and a synchronization signal superposed thereon.

First, in the imaging device 300, the storage section 302 stores selection information for selecting an object.

The photoreceiving section 303 receives invisible light which is sent out from all phototransmitters 100 (100A, 100B, and 100C). As was described in the first embodiment, the invisible light is typically infrared radiation, and contains a synchronization signal and selection information.

The capture determination section 304 compares the selection information contained in the invisible light received by the photoreceiving section 303 against the selection information which is stored in the storage section 302, and determines whether they match or not.

The image input section 305 takes in an image in the manner described in the first embodiment, and passes the image to the image processing section 306.

As in the case of the first embodiment, the image processing section 306 performs necessary processing for the image which is sent from the image input section 305, and thereafter passes the processed image to the image displaying section 307.

As in the case of the first embodiment, the image displaying section 307 displays the image which has been sent from the image processing section 306.

In the control device 200, the control section 202 instructs all of the phototransmitters 100 in the present object identification system to transmit a synchronization signal and selection information.

As described in the first embodiment, each phototransmitter 100 is assigned to an object. In accordance with an instruction from the control device 200, each phototransmitter 100 generates and sends out invisible light having a synchronization signal and selection information superposed thereon. In other words, the phototransmitter 100 emits light in response to an instruction from the control device 200.

Next, the object identification method will be described with reference to the sequence chart of FIG. 7.

First, to the imaging device 300; the user inputs information concerning a target object (e.g., the object A), via key operations. The information which has been input is stored to the storage section 302 of the imaging device 300 as selection information for specifying an object (step ST21).

Next, the control device 200 instructs all of the phototransmitters 100, which are respectively assigned to all of the objects, to transmit selection information and a synchronization signal (step ST22, sequence SQ22).

In response to an instruction from the control device 200, all of the phototransmitters 100 send out invisible light having selection information and a synchronization signal superposed thereon, at respectively different points in time as shown in FIG. 7 (sequence SQ23).

If the user brings the imaging device 300 near an object in this state, the photoreceiving section 303 of the imaging device 300 receives the invisible light which is being sent out from the phototransmitter 100 assigned to the particular object which the imaging device 300 has been brought near (step ST23).

In the imaging device 300, the capture determination section 304 compares the selection information which is superposed on the received invisible light against the selection information which is previously stored in the storage section 302, and determines whether they match or not (step ST24).

If step ST24 determines YES, the image input section 305 takes in an image (step ST25). Preferably, the image input section 305 stores the image to an internal frame memory based on the synchronization signal which is sent together with the selection information. Such an image may be stored to a storage medium such as an SD card®, in accordance with the user's instruction. If step ST24 determines NO, the image input section 305 does not take in any image.

Thereafter, the image displaying section 307 receives via the image processing section 306 the image which has been taken in by the image input section 305, and displays the image (step ST26).

As described above, according to the present embodiment, as in the case of the first embodiment, a captured image concerning the object (e.g., the object A) which is indicated in the selection information as desired by the user is automatically displayed on the image displaying section 307 of the imaging device 300. At this time, the emission of the phototransmitter 100 is also automatically displayed in the captured image, thus enabling the user to distinguish the object very clearly.

According to the third embodiment, the control device 200 causes all phototransmitters 100 to emit light at respectively different points in time. In other words, since the control device 200 is not required to cause only the phototransmitter 100 as desired by the user to emit light, there is no need to receive selection information from the imaging device 300. As a result, unlike in the first embodiment, it is no longer necessary to provide communication sections 201 and 301 in the control device 200 and the imaging device 300, respectively. Therefore, various costs associated with the object identification system can be reduced.

### Fourth Embodiment

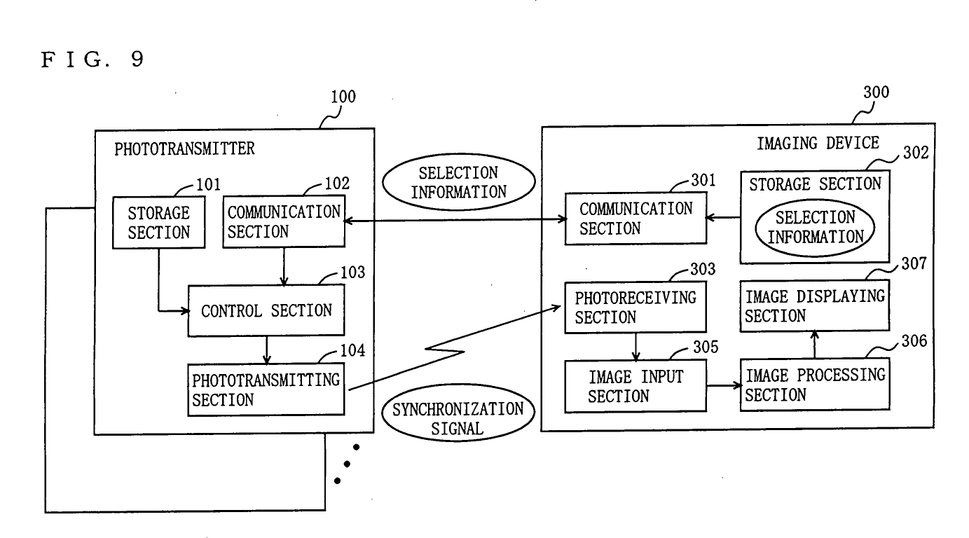

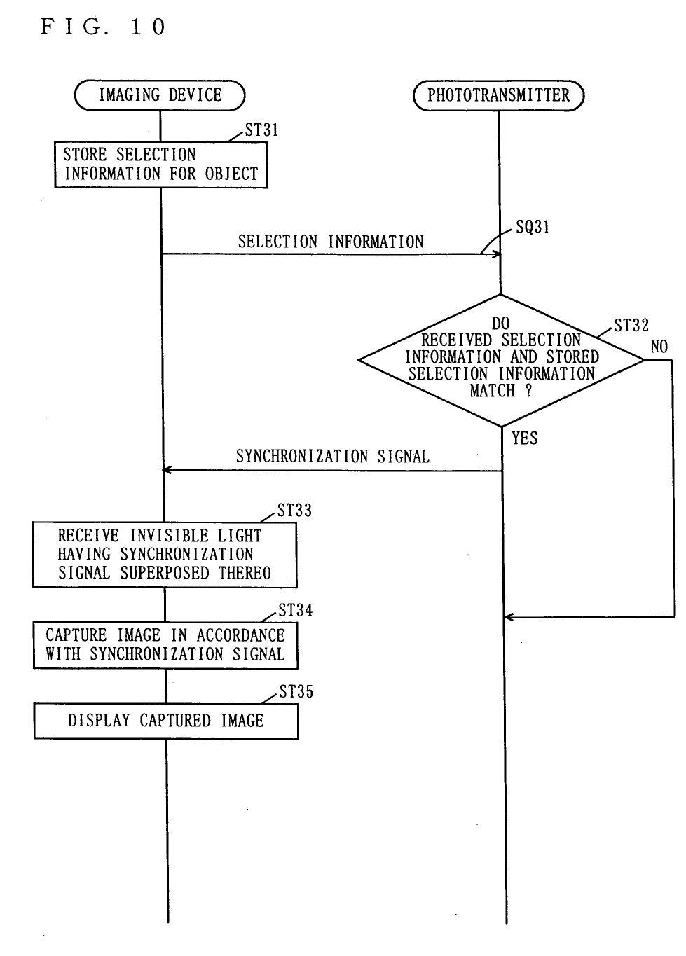

Next, an object identification system and an object identification method according to a fourth embodiment of the present invention will be described with reference to the block diagram of FIG. 9 and the sequence chart of FIG. 10.

As shown in FIG. 9, the present object identification system comprises: phototransmitters 100 provided corresponding to respective objects; and an imaging device 300 which is capable of establishing a communication link with each phototransmitter 100. A typical example of the imaging device 300 is a digital camera, or a cellular phone equipped with a camera. The phototransmitter 100 and the imaging device 300 perform wired communications or wireless communications with each other.

Each phototransmitter 100 includes a storage section 101, a communication section 102, a control section 103, and a phototransmitting section 104.

The storage section 101 previously stores selection information concerning an object assigned to each phototransmitter 100.

The communication section 102 receives selection information which is sent from the imaging device 300.

The control section 103 compares the selection information received by the communication section 102 against the selection information which is stored in the storage section 101, and determines whether they match or not.

If it is determined by the control section 103 that the two pieces of selection information match, the phototransmitting section 104 sends invisible light having a synchronization signal superposed thereon. The invisible light has characteristics as described in the first embodiment.

The imaging device 300 includes a communication section 301, a storage section 302, a photoreceiving section 303, an image input section 305, an image processing section 306, and an image displaying section 307.

After establishing a communication link with the communication section 102 of the phototransmitter 100, the communication section 301 transmits selection information for selecting an object to the communication section 102.

The storage section 302 stores the selection information for selecting an object.

The photoreceiving section 303 receives invisible light which is sent from the phototransmitter 100, with the synchronization signal being superposed on the invisible light.

Upon receiving the synchronization signal superposed on the invisible light which is received by the photoreceiving section 303, the image input section 305 takes in an image by using an optical system and a photoreceiving device (neither of which is shown) composing the image input section 305, and passes the image to the image processing section 306. The photoreceiving device has a sensitive range which includes the wavelength of the invisible light emitted by the phototransmitters 100.

The image processing section 306 passes the image which has been sent from the image input section 305 to the image displaying section 307. At this time, the image processing section 306 preferably processes the image so that the emission by the phototransmitter 100 becomes more outstanding. Note that the function of the image processing section 306 may alternatively be imparted to the image input section 305 or the image displaying section 307.

The image displaying section 307 displays the image which has been sent from the image processing section 306. Since the wavelength of the invisible light falls within the sensitive range of the image input section 305, the user is able to visually perceive the emission by the phototransmitter 100 on the displayed image.

Next, the object identification method will be described with reference to the sequence chart of FIG. 10.

First, to the imaging device 300, the user inputs information concerning a target object via key operations. The object information which has been input is stored to the storage section 302 of the imaging device 300 as selection information for specifying the object (step ST31).

Next, the imaging device 300 reads the selection information which is stored to the storage section 302, and transmits the selection information from the communication section 301 to each phototransmitter 100 (sequence SQ31).

Next, if the communication section 101 of each phototransmitter 100 receives the signal from the imaging device 300, the control section 103 compares the received selection information against the selection information which is previously stored in the storage section 302 of the phototransmitter 100, and determines whether they match or not (step ST32).

If step ST32 determines YES, the phototransmitting section 104 sends out invisible light having a synchronization signal superposed thereon (sequence SQ32). If it is determined NO, the phototransmitting section 104 does not send out invisible light.

In the imaging device 300, the photoreceiving section 303 receives the invisible light which has been sent out from the phototransmitting section 104, and passes the synchronization signal superposed on the received invisible light to the image input section 305 (step ST33). As described in the first embodiment, the image input section 305 inputs an image based on the synchronization signal (step ST34). Also as described in the first embodiment, the image displaying section 307 displays an image which has been processed by the image processing section 306 (step ST35).

As described above, according to the present embodiment, as in the case of the first embodiment, a captured image concerning the object (e.g., the object A) which is indicated in the selection information as desired by the user is automatically displayed on the image displaying section 307 of the imaging device 300. At this time, the emission of the phototransmitter 100 is also automatically displayed in the captured image, thus enabling the user to distinguish the object very clearly.

Furthermore, according to the present embodiment, each phototransmitter 100 directly communicates with the imaging device 300 to determine whether or not to send out invisible light. Therefore, there is no need to provide a control device 200. As a result, the structure of the present object identification system is simplified relative to that according to the first embodiment, and various costs associated therewith can be reduced.

### Fifth Embodiment

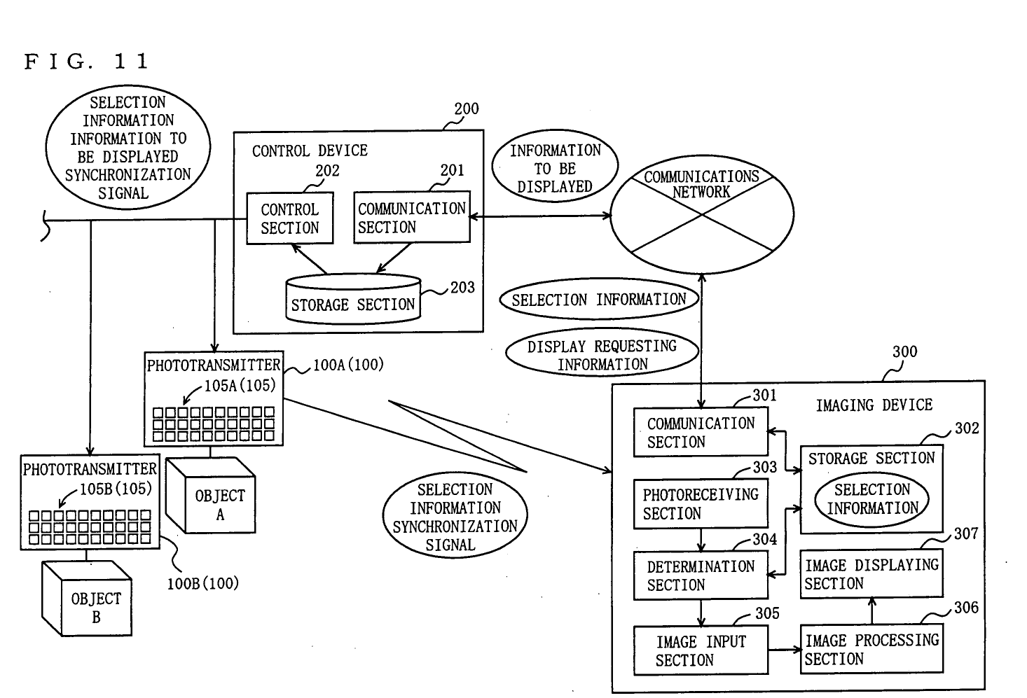

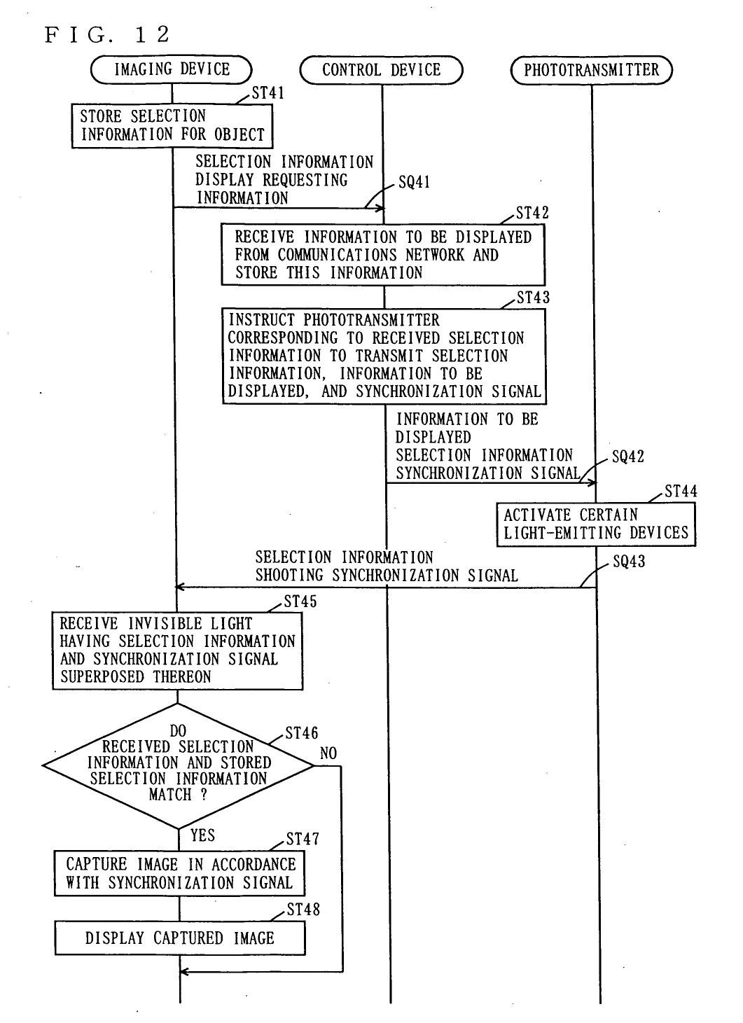

Next, an object identification system and an object identification method according to a fifth embodiment of the present invention will be described with reference to the block diagram of FIG. 11 and the sequence chart of FIG. 12. The present object identification system has the same construction as that described in the first embodiment except for the following aspects. Therefore, in FIG. 11, elements which correspond to those in FIG. 2 are indicated by the same reference numerals as those used therein. There are structural differences between the two embodiments in that phototransmitters 100 (100A and 100B are shown in the figure) send out invisible light from a displaying section 105 (105A and 105B are shown in the figure), and that the control device 200 comprises a storage section 203. Due to such general structural differences, the operations of the phototransmitters 100, the control device 200, and the imaging device 300 are also different from those in the first embodiment, as described below.

The communication section 301 of the imaging device 300 transmits selection information for selecting an object and display requesting information to the control device 200, via a communications network. As used herein, the display requesting information is information for requesting the control device 200 to display information to be displayed, which is previously assigned to an object, on the displaying section 105.

The storage section 302 stores selection information for selecting an object.

The photoreceiving section 303 receives invisible light (refer to the first embodiment) which is sent out from the phototransmitter 100.

The capture determination section 304 compares the selection information contained in the invisible light received by the photoreceiving section 303 against the selection information which is stored in the storage section 302, and determines whether they match or not.

The image input section 305 takes in an image in the manner described in the first embodiment, and passes the image to the image processing section 306.

As in the case of the first embodiment, the image processing section 306 performs necessary processing for the image which is sent from the image input section 305, and thereafter passes the processed image to the image displaying section 307.

As in the case of the first embodiment, the image displaying section 307 displays the image which has been sent from the image processing section 306.

In the control device 200, the communication section 201 receives the selection information and the display requesting information which are transmitted from the communication section 301 of the imaging device 300. Moreover, from another source (e.g., a Web server), the communication section 201 receives information to be displayed which is assigned to the object specified by the received display requesting information, via the communications network. The received information to be displayed and selection information are stored to the storage section 203 of the control device 200.

The control section 202 instructs only the phototransmitter 100 that is assigned to the object specified by the selection information stored in the storage section 203 to transmit a synchronization signal and selection information and display information to be displayed. For example, if the selection information is for selecting the object A, only the phototransmitter 100A corresponding to the object A is instructed as above.

In the phototransmitter 100, the displaying section 105 is, for example, a display panel having a matrix of light-emitting devices for emitting invisible light having a synchronization signal and selection information superposed thereon. In the displaying section 105 as such, certain light-emitting devices emit light in accordance with the information to be displayed which is sent from the control section 202. By thus allowing certain light-emitting devices to emit light, a brief explanation or a price of an object, for example, can be displayed by the imaging device 300. FIG. 11 illustrates an example where only the phototransmitter 100A is emitting invisible light to output such object information.

Next, the object identification method will be described with reference to the sequence chart of FIG. 12.

First, to the imaging device 300, the user inputs information concerning a target object (e.g., the object A), via key operations, for example. The information which has been input is stored to the storage section 302 as selection information for specifying the object (step ST41).

Next, the imaging device 300 reads from the storage section 302 the selection information which is stored to the storage section 302, and transmits the read selection information and the display requesting information from the communication section 301 to the control device 200, via the communications network (sequence SQ41).

Next, upon receiving the signal from the imaging device 300, the control device 200 receives from the communications network the information to be displayed which is assigned to the object specified by the display requesting information, and stores the information to the storage section 302 (step ST42). Although an example is illustrated where the information to be displayed is acquired by being received from a separate source via the communications network, the information to be displayed may alternatively be previously stored in the control device 200 or the phototransmitter 100.

The control section 202 instructs only the phototransmitter 100 (e.g., 100A) which is assigned to an object (e.g., the object A) corresponding to the received selection information to transmit selection information, a synchronization signal, and information to be displayed (step ST43, sequence SQ42).

In the phototransmitter 100 (e.g., 100A), in response to an instruction from the control section 202, the displaying section 105 (e.g., 105A) outputs invisible light having a synchronization signal and selection information superposed thereon from certain light-emitting devices. Thus, the phototransmitter 100 outputs object information (step ST44). Furthermore, as in the first embodiment, the phototransmitter 100 sends out invisible light having selection information and synchronization information superposed thereon (sequence SQ43).

If the user brings the imaging device 300 near the object in this state, the photoreceiving section 303 of the imaging device 300 receives invisible light which is being sent out from the phototransmitter 100 (e.g., 100A) (step ST45).

Next, the capture determination section 304 of the imaging device 300 compares the selection information which is superposed on the received invisible light against the selection information which is previously stored in the storage section 302, and determines whether they match or not (step ST46).

If step ST46 determines YES, the image input section 305 takes in an image (step ST47). Preferably, the image input section 305 stores the image to an internal frame memory based on the synchronization signal which is sent together with the selection information. Such an image may be stored to a storage medium such as an SD card®, in accordance with the user's instruction. If step ST46 determines NO, the image input section 305 does not take in any image.

Thereafter, the image displaying section 307 receives via the image processing section 306 the image which has been taken in by the image input section 305, and displays the image (step ST48). As described above, since the photoreceiving device of the imaging device 300 is sensitive to the wavelength of the invisible light, information concerning the object which is output by the displaying section 105 is being shown in the displayed image in a form visually perceivable by the user.

As described above, according to the present embodiment, a captured image concerning the object (e.g., the object A) which is indicated in the selection information as desired by the user is automatically displayed on the image displaying section 307 of the imaging device 300. At this time, the emission of the phototransmitter 100 is also automatically displayed in the captured image, thus enabling the user to distinguish the object very clearly.

The present embodiment provides a further advantage over the first embodiment in that, since certain light-emitting devices in the displaying section 105 are driven to emit light, the user can further obtain information concerning the object (information to be displayed) by looking at the image which is displayed on the imaging device 300.

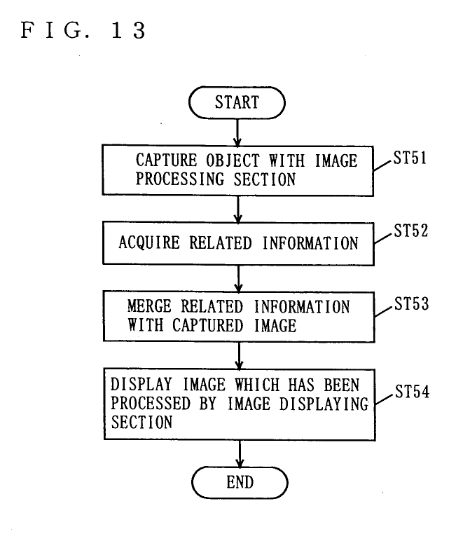

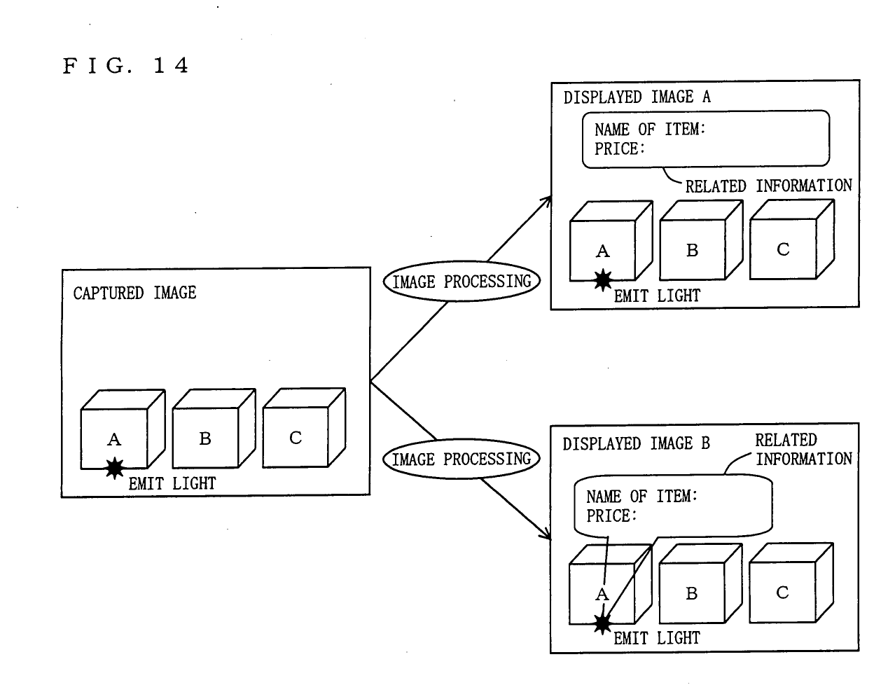

In accordance with the object identification system and the object identification method of the fifth embodiment, information concerning an object is displayed at the imaging device 300. However, in the object identification systems and the object identification methods according to the first to fourth embodiments, the phototransmitter 100 may superpose the information concerning an object on the invisible light to be sent, and, as shown in FIG. 13, the image processing section 306 of the imaging device 300 may merge an image which has been taken in by the image input section 305 with related information which is superposed on the invisible light received by the photoreceiving section 303 (steps ST51 to ST54). In this case, as shown in FIG. 14, the displayed image on the image displaying section 307 contains an object, a certain phototransmitter 100 emitting light, and related information. The image processing section 306 may generate an image in which the object is displayed with some emphasis, by surrounding the object with a line or pointing to the object with an arrow.

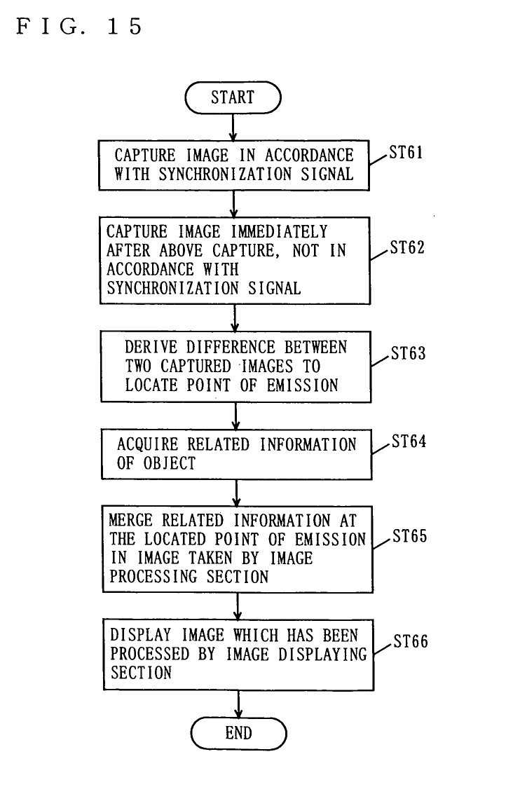

In the object identification system and the object identification method according to the first to fifth embodiments, as shown in FIG. 15, the image input section 305 of the imaging device 300 may receive two input images, i.e., one which is based on a synchronization signal and another which is not based on a synchronization signal, and the image processing section 306 may perform a process which takes a difference between the two images which have been captured, such that only the portion representing the emission of the phototransmitter 100 is left after the process. Furthermore, the image processing section 306 may merge the related information which is acquired in the above manner, in the vicinity of the emitting portion of the phototransmitter 100. Thus, the image displaying section 307 of the imaging device 300 will display only the emission of the phototransmitter 100 and the related information (steps ST61 to ST66). As a result, the user is enabled to find the object in a direction in which the optical system of the imaging device 300 is oriented.

In the object identification system and the object identification method according to the first to fifth embodiments, it is assumed that one phototransmitter 100 is assigned to one object. Alternatively, one phototransmitter 100 may be assigned to a plurality of objects.

### Sixth Embodiment

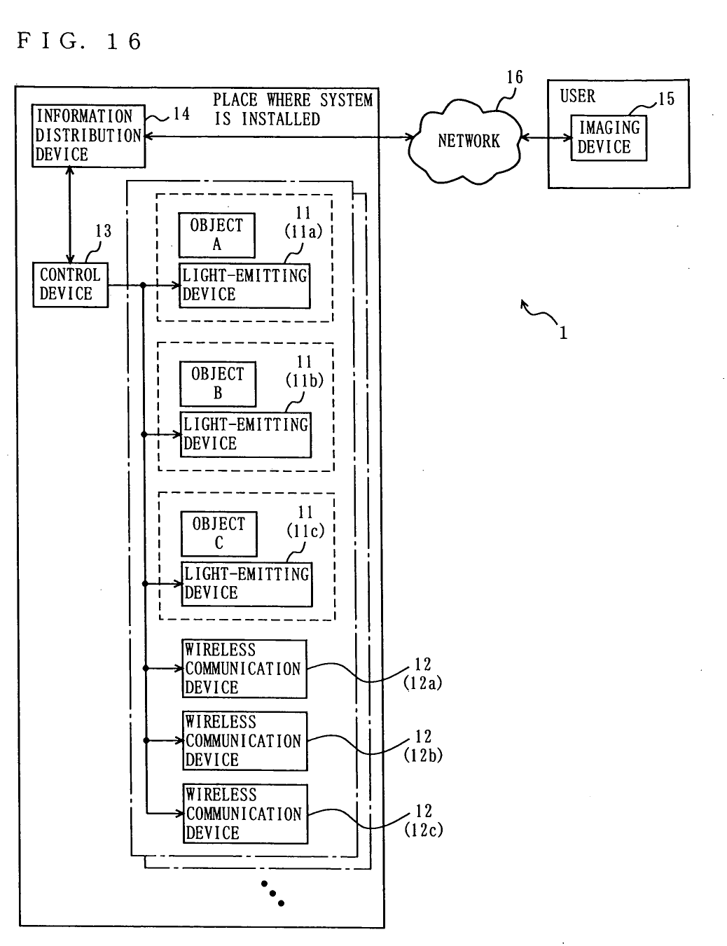

FIG. 16 is a block diagram illustrating an overall structure of an object identification system 1 according to a sixth embodiment of the present invention. In FIG. 1, the present system 1 comprises: at least one phototransmitter 11, at least one wireless communication device 12, a control device 13, an information distribution device 14, and an imaging device 15. Most of the elements of the above system 1 are to be installed in a place, e.g., a shop or an exhibition, where the user needs to look for an item which is of interest to the user (i.e., an object). In a place where the present system 1 is installed, at least one phototransmitter 11, at least one wireless communication device 12, and the control device 13 are to be installed. FIG. 16 exemplifies three phototransmitters 11a, 11b, and 11c as the phototransmitters 11, and three wireless communication devices 12a, 12b, and 12c as the wireless communication devices 12.

Next, the respective elements to be installed in such a place will be described in detail.

Each phototransmitter 11 generate invisible light under the control of the control device 13, with a synchronization signal (described later) being superposed on the invisible light. Invisible light contains wavelengths which are not perceived by the human eyes, but which fall within a sensitive range of a photoreceiving device (not shown), such as a CCD (Charge Coupled Device), that is comprised by the imaging device 15. A typical example of such invisible light is infrared radiation. Other types of invisible light exist besides infrared radiation, such as ultraviolet rays. However, it is preferable that the phototransmitter 11 can emit infrared radiation because it facilitates applications for data communications (e.g., IrDA).

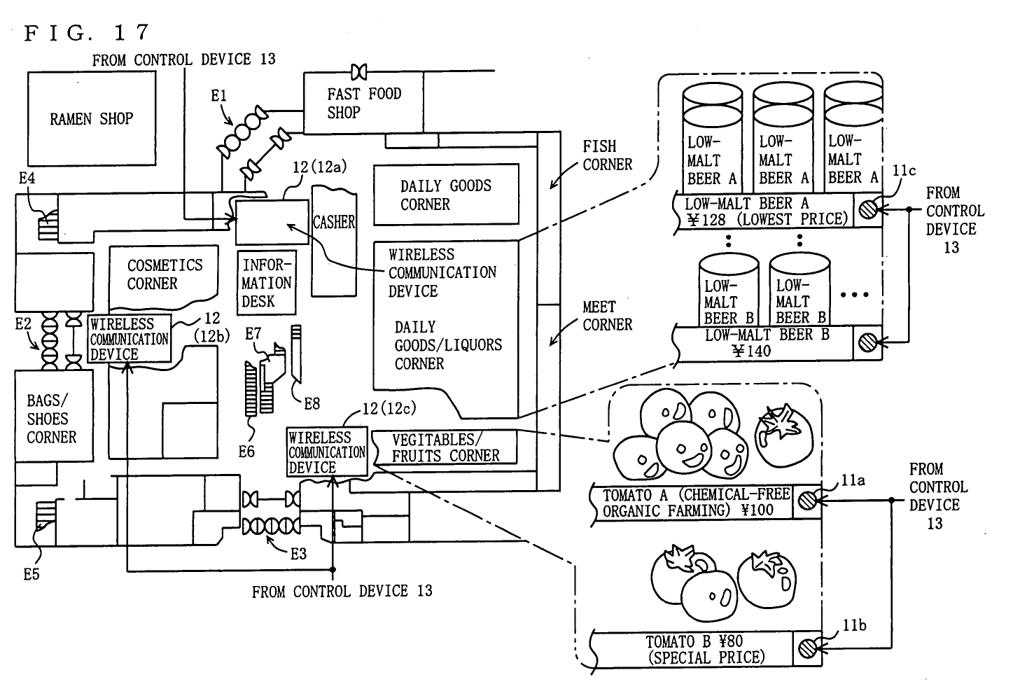

FIG. 17 is a schematic diagram illustrating exemplary installation of phototransmitters 11 in the case where the present system 1 is installed in a shop. In FIG. 17, each phototransmitter 11 is assigned to an item which is of interest to the user (object). In order to assign the phototransmitter 11 to an object, in the present embodiment, the phototransmitter 11 is to be placed in the vicinity of the object. Furthermore, the light-emitting surface of the phototransmitter 101 is oriented toward a position where the user is expected to come to a stop to look at the object. For example, the phototransmitter 11a is placed in the vicinity of an object, a tomato A, and the light-emitting surface thereof is oriented toward a position where the user is expected to come to a stop to look at the tomato A. Moreover, the phototransmitter 11b is placed in the vicinity of another object, a tomato B, and the light-emitting surface thereof is oriented toward a position where the user is expected to come to a stop to look at the tomato B. Furthermore, the phototransmitter 11c is placed in the vicinity of a still another object, low-malt beer A, and the light-emitting surface thereof is oriented toward a position where the user is expected to come to a stop to look at the low-malt beer A.

For the sake of explanation, the tomato A is assumed to have been obtained through chemical-free organic farming. The tomato B and the low-malt beer A are assumed to be bargain items.

It is still more preferable that the invisible light has rectilinearity. Although infrared radiation spreads out to a certain degree, infrared radiation far excels in rectilinearity as compared to radiowaves, for example. Due to such rectilinearity, the infrared radiation which is emitted from a given phototransmitter 11 near a position where the user is expected to come to a stop is not susceptible to the interference of the infrared radiation from any other phototransmitter 11. Based on such rectilinearity, it becomes possible to assign a phototransmitter 11 to each of a plurality of objects which are displayed close to one another. For example, in the example of FIG. 17, the phototransmitters 11a and 11b are located near each other, the infrared radiation emitted from each of them is rectilinear. Therefore, for example, the imaging device 15 of a user who is interested in the object tomato A can properly receive the synchronization signal which is superposed on the infrared radiation emitted from the phototransmitter 11a, without the interference of the infrared radiation emitted from the phototransmitter 11b.

Referring back to FIG. 16, each wireless communication device 12 performs a wireless communication with an imaging device 15 which is located within a coverage area of the wireless communication device 12, under the control of the control device 13. Typically, each wireless communication device 12 transmits an area signal (described later) to the imaging device 15. Unlike the phototransmitter 11, the wireless communication device 13 is not to be assigned to an object itself object, but is installed in order to notify to the imaging device 15 of the user that the object exists near the user. Therefore, it is preferable that the wireless communication device 13 has a relatively broad coverage area. Examples of such a wireless communication device 12 are those complying with IEEE (Institute of Electrical and Electronics Engineers) 802.11, or the Bluetooth® standards.

FIG. 17 is also a schematic diagram illustrating exemplary installation of the wireless communication device 12. In FIG. 17, within the place in which the present system 1 is installed, the wireless communication device 12 covers areas which are crowded with people as its coverage area. For example, within the shop (as a place in which the present system 1 is installed), the wireless communication device 12a encompasses the neighborhood of the front entrance E1 as its coverage area. The wireless communication device 102b covers the neighborhood of a west entrance E2 and stairways E4 and E5 as its coverage area in the shop. Furthermore, the wireless communication device 102c covers the neighborhood of a south entrance E3, an ascending escalator E6, a stairway E7, and a descending escalator E8 as its coverage area in the shop.

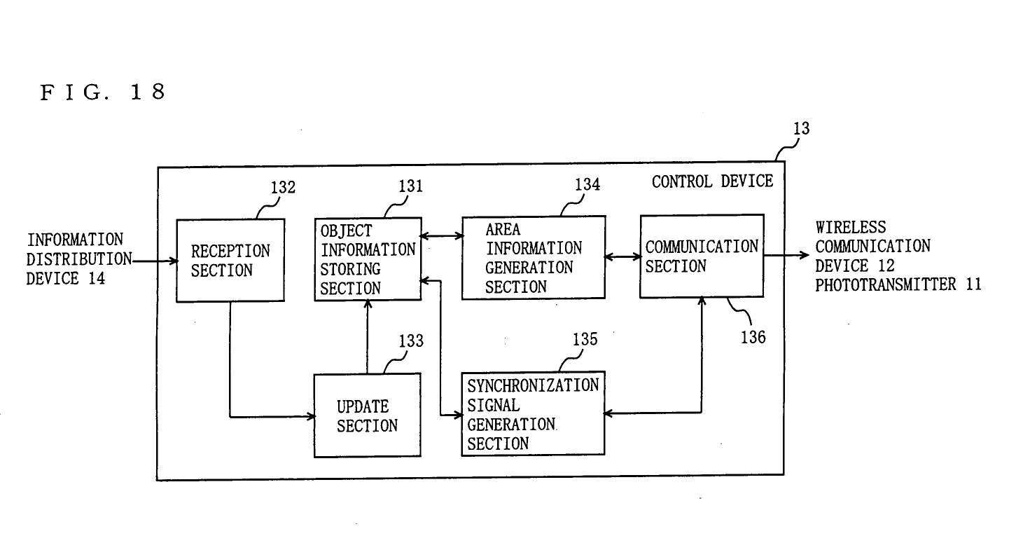

Referring back to FIG. 16, the control device 13 mainly controls the emission by the phototransmitter 11 and the communications by the wireless communication device 12. FIG. 18 is a block diagram illustrating a detailed structure of the control device 13. Hereinafter, elements of the control device 13 will be described with reference to FIG. 18. In FIG. 18, the control device 13 includes an object information storing section 131, a reception section 132, an update section 133, an area information generation section 134, a light emission instructing section 135, and a communication section 136.

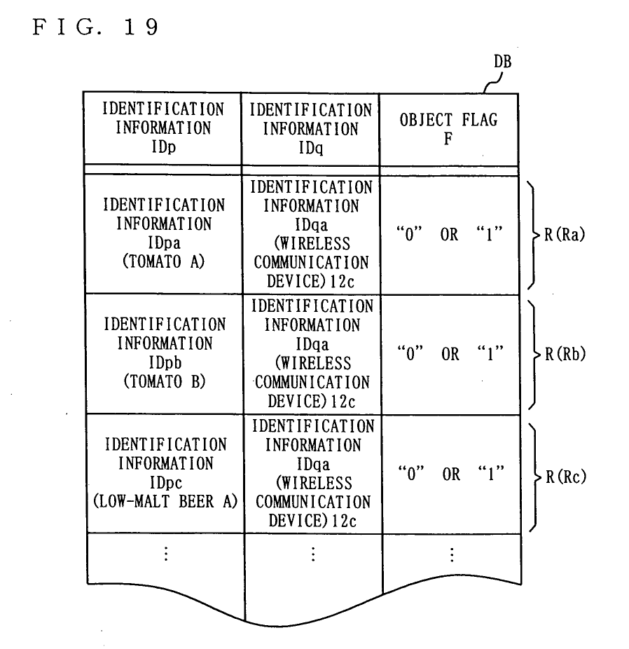

The object information storing section 131 stores an object database DB as shown in FIG. 19. For each object to which a phototransmitter 11 is assigned, the object database DB includes an object record R, which is composed of a combination of: one piece of identification information IDp; at least one piece of identification information IDq; and an object flag F. As object records R, FIG. 19 exemplifies three object records Ra, Rb, and Rc for objects A, B, and C, respectively.

The identification information IDp is information for uniquely identifying an object. In the example shown, object records Ra, Rb, and Rc include identification information IDpa, IDpb, and IDpd for objects A, B, and C, respectively.

The identification information IDq is information for uniquely identifying a wireless communication device 102. Specifically, the identification information IDq specifies a wireless communication device 12 which is placed near the object specified by the identification information IDp in the same record. In the example shown in the figure, object records Ra, Rb, and Rc contain, respectively, identification information IDqa, IDqb, and IDqc of wireless communication devices 12c. Alternatively, the object record R may only contain identification information IDq of a wireless communication device 12 which is placed the closest to the object specified by the identification information IDp in the same record.

The object flag F is information indicating, with respect to the object specified by the identification information IDp in the same record, whether selection information has been transmitted to the information distribution device 14 from the imaging device 15 carried by the user. The object flag F as such is updated by the update section 133. In the present embodiment, an object flag F “0” indicates that no selection information for the object has been received by the information distribution device 14, and an object flag F “1” indicates that selection information with respect to the object has been received by the information distribution device 14. FIG. 19 illustrates an exemplary case where the information distribution device 14 has only received selection information with respect to the object A.

The reception section 132 receives the selection information which has been transmitted from the information distribution device 14, and passes the selection information to the update section 133.

Each time selection information is sent from the reception section 132, the update section 133 extracts the identification information IDp which is contained in the received selection information. Thereafter, the update section 133 accesses the object database DB to update the value of the object flag F to “1” which is in the same record as the extracted identification information IDp. As will be specifically described later, by checking the object flag F, the light emission instructing section 135 generates a synchronization signal for each object, and passes the synchronization signal to the communication section 136. After such a synchronization signal has been generated at least once, the update section 133 updates the value of the currently-checked the object flag F to “0”.

The area signal generation section 134 generates area information indicating that the user is located near an object of interest, and instructs the communication section 136 to transmit the generated area information to the wireless communication device 12 which is currently performing a communication with the user's imaging device 15.

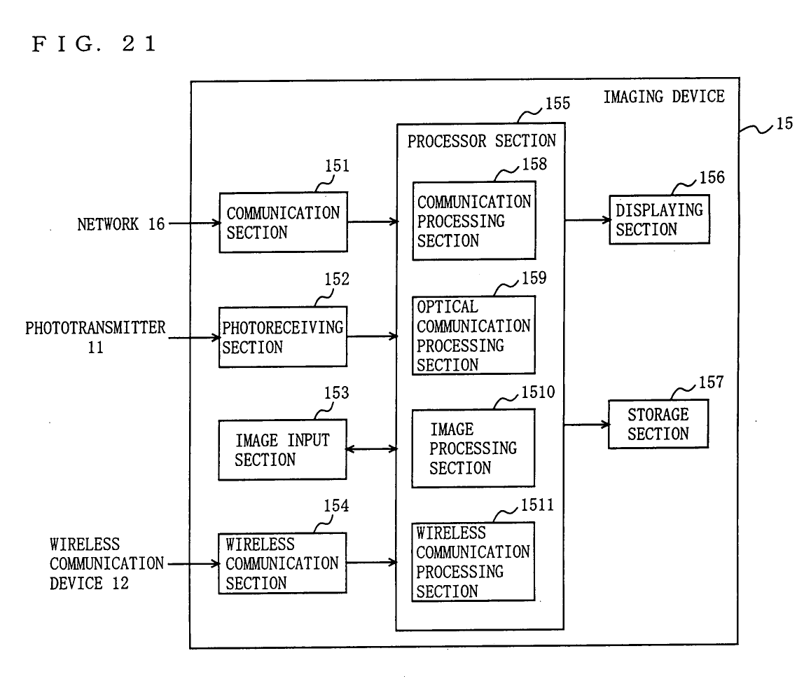

The light emission instructing section 135 generates a synchronization signal, which causes a displaying section 153 (see FIG. 21) of the imaging device 15 to display the presence of an object which is of interest to the user. As a preferable example, in the present embodiment, the synchronization signal is also a signal for notifying the imaging device 15 of the timing as to when to take in an image of the object. The light emission instructing section 135 instructs the communication section 136 to transmit the generated synchronization signal to a phototransmitter 11 which is assigned to the object of interest.

In response to an instruction from the area signal generation section 134 or the light emission instructing section 135, the communication section 136 transmits the area signal or the synchronization signal generated thereby, respectively, to the relevant wireless communication device 12 or phototransmitter 11.

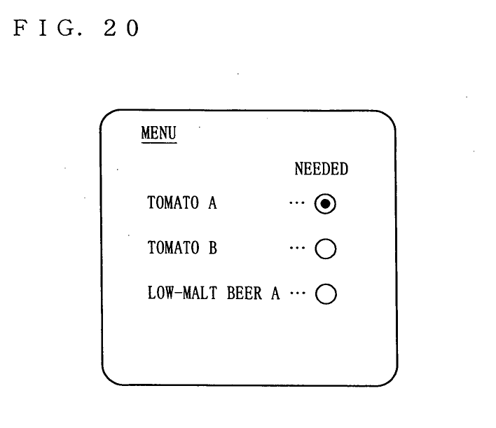

Referring back to FIG. 16, via the network 106, the information distribution device 14 preferably distributes to the imaging device 15 menu information concerning all of the objects which are present in the place where the present system 1 is installed. As shown in FIG. 20, the menu information is constructed so as to enable the user to indicate whether the user needs each object or not. In the example shown in FIG. 20, the menu information is constructed so as to enable the user to indicate whether the user needs each of the following objects: the tomato A, the tomato B, the low-malt beer A, and the low-malt beer B. Furthermore, by using such menu information, the information distribution device 14 acquires selection information, i.e., information specifying the object which the user needs, via the network 16. The information distribution device 14 transmits the selection information which has been thus acquired to the control device 13.

Referring again to FIG. 16, the imaging device 15, which is to be carried by the user, at least has a data communications function using invisible light and an imaging function. A typical example of such an imaging device 15 is a cellular phone or a digital camera. Preferably, the imaging device 15 has a function of connecting to the network 16. FIG. 21 is a block diagram illustrating a detailed structure of the imaging device 15. Hereinafter, with reference to FIG. 21, the respective elements of the imaging device 15 will be described. In FIG. 21, the imaging device 15 includes a communication section 151, a photoreceiving section 152, an image input section 153, a wireless communication section 154, a processor section 155, a displaying section 156, and a storage section 157. The processor section 155 includes a communication processing section 158, an optical communication processing section 159, an image processing section 1510, and a wireless communication processing section 1511.

The communication section 151 sends out various data which have been generated by the processor section 155 onto the network 16. The communication section 151 receives various data which have been transmitted via the network 16, and passes the data to the processor section 155. Typical data to be received by the communication section 151 is menu information which is sent from the information distribution device 14. Typical data to be sent out by the communication section 151 is a transmission request for the menu information or selection information.

The photoreceiving section 152 receives the invisible light which is sent out by the phototransmitter 11, and extracts various data which are superposed on the received invisible light. The photoreceiving section 152 passes the various data which have been extracted to the processor section 155.

Although omitted from the figure, the image input section 153 includes an optical system and a photoreceiving device (e.g., a CCD). Based on this construction, the image input section 153 takes in an image of a direction in which a lens of the imaging device 15 is oriented, and passes the image thus taken in to the processor section 155. The photoreceiving device of the image input section 153 is sensitive to the invisible light emitted by the phototransmitter 100. In the image input section 153, the lens is preferably placed near the photoreceiving section 152. More specifically, the photoreceiving section 152 and the lens are to be disposed in such a manner that, while data communications using a visible light ray is being performed between the photoreceiving section 152 and the phototransmitter 11, the lens is oriented in the direction of the object to which the phototransmitter 11 is assigned. As a result, even in the case where the invisible light has rectilinearity, the image input section 153 is able to take in an image representing the object.

The wireless communication section 154 transmits various data which have been generated by the processor section 155, via a wireless link that has been established with the wireless communication device 12. Moreover, via a wireless link, the wireless communication section 154 receives various data (e.g., area information) which are sent from the wireless communication device 12, and passes the data to the processor section 155.

In the processor section 155, the communication processing section 158 processes various data which have been received by the communication section 151, and generates various data to be sent out by the communication section 151. The optical communication processing section 159 processes various data which are sent from the photoreceiving section 152 (e.g., a synchronization signal and selection information). The image processing section 1510 processes an image signal which is sent from the image input section 153. The wireless communication processing section 1511 processes various data which are sent from the wireless communication section 154 (e.g., area information).

In accordance with various data which are sent from the processor section 155 (menu information or a captured image), the displaying section 156 displays an image. The storage section 157 stores various data which are sent from the processor section 155 (e.g., selection information or the captured image). The storage section 157 preferably stores identification information for uniquely identifying the imaging device 15.

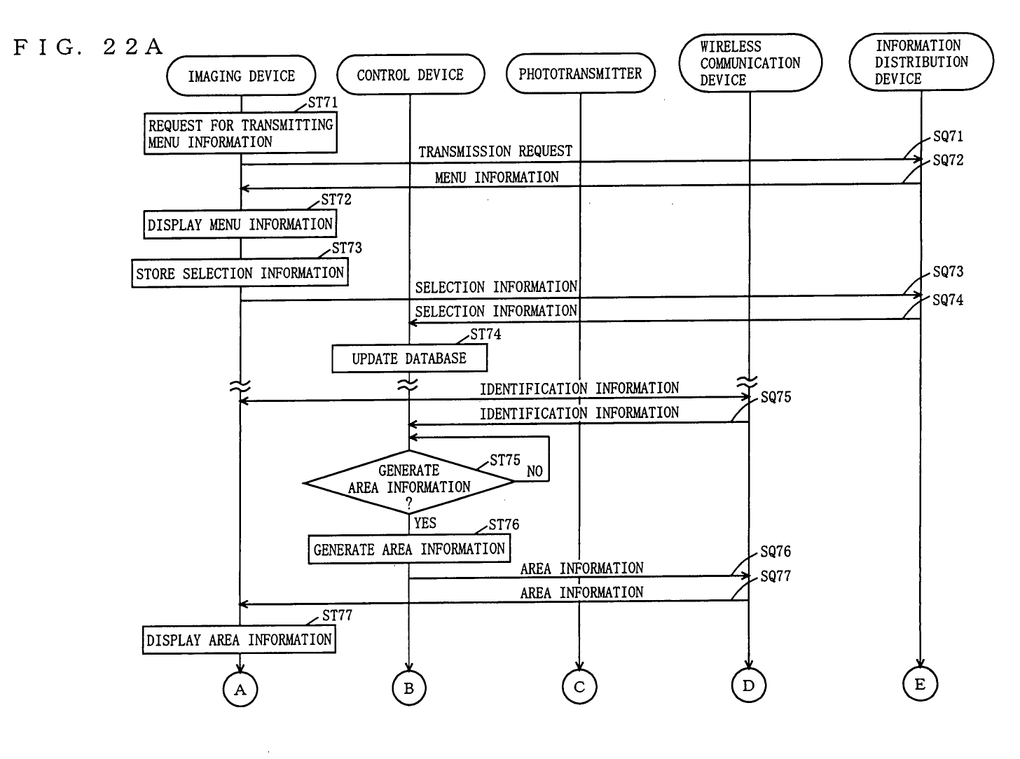

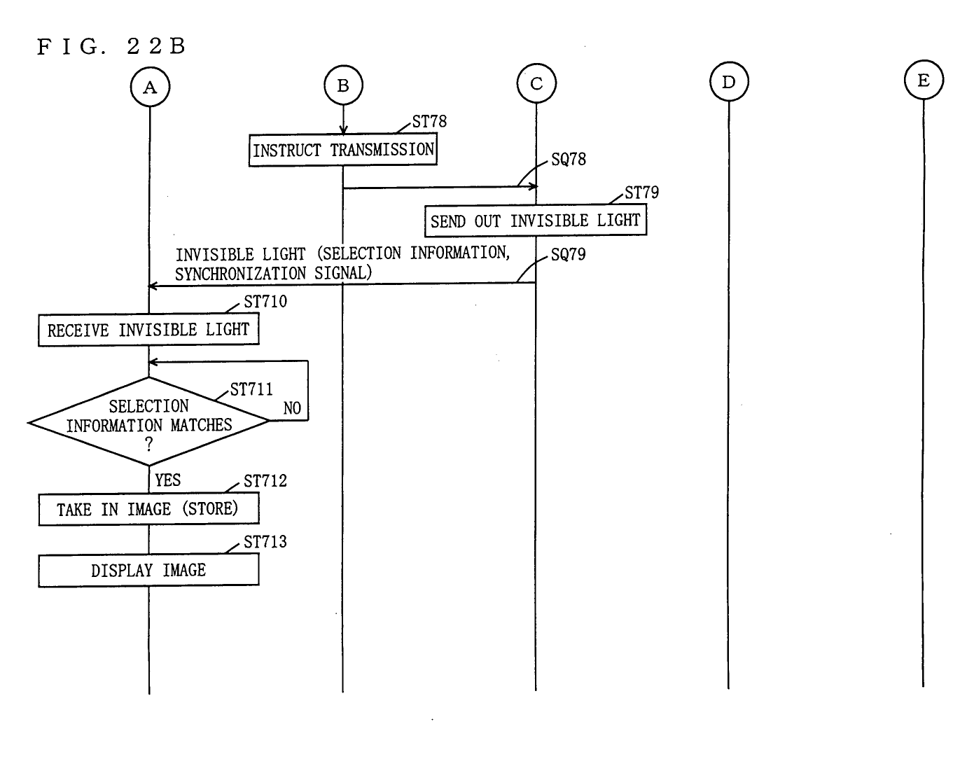

Next, with reference to the sequence chart of FIG. 22A and FIG. 22B, the operation of the object identification system 1 shown in FIG. 16 will be described.

First, in the imaging device 15, the communication processing section 158 generates, in accordance with the user's operation, a transmission request for the information distribution device 14 to send menu information, and sends the transmission request onto the network 16 via the communication section 151 (FIG. 22A; step ST71, sequence SQ71). Upon receiving the transmission request from the imaging device 15 via the network 16, the information distribution device 14 transmits menu information which is retained in itself (sequence SQ72). Upon receiving the menu information via the communication section 151, the communication processing section 158 displays the received menu information (see FIG. 20) on the displaying section 156 (step ST72).

By referring to the menu information which is displayed in the aforementioned manner, the user operates the imaging device 15 to select at least one object as desired, and stores to the storage section 157 selection information containing the object (s) having been selected by the user. The communication processing section 158 sends the same selection information onto the network 16 via the communication section 151 (step ST73, sequence SQ73). Preferably, the selection information includes identification information which is capable of uniquely identifying the imaging device 15. Upon receiving the selection information from the imaging device 15 via the network 16, the information distribution device 14 transfers the received selection information to the control device 13 (sequence SQ74).

Upon receiving the selection information from the information distribution device 14, the control device 13 updates the object database DB (see FIG. 19) (step ST74). Specifically, upon receiving the selection information from the information distribution device 14 via the reception section 132, the update section 133 selects an object record R which is assigned to the object specified by the received selection information. Thereafter, the update section 133 sets the object flag F contained in the currently-selected object record R to “1”. In a preferable example, the identification information of the imaging device 15 is registered to the currently-selected object record R.

Thereafter, the user goes to the place where the present system 1 is installed (see FIG. 17), while carrying the imaging device 15. When the user enters the place through one of the entrances E1 to E3, the wireless communication section 154 of the imaging device 15 establishes a wireless communication link with one of the wireless communication devices 12 (i.e., one of 12a to 12c). Thereafter, in the imaging device 15, the wireless communication processing section 1511 extracts the identification information which is stored in the storage section 157, and, via the wireless communication section 154, transmits the identification information to the wireless communication device 12 with which it is currently communicating (sequence SQ75). Upon receiving the identification information from the imaging device 15, the wireless communication device 12 transfers the received identification information to the control device 13 (sequence SQ76).

In the control device 13, upon receiving identification information from the imaging device 15 via the communication section 136, the area information generation section 134 accesses the object information storing section 131. Thereafter, area information generation section 134 determines whether or not to generate area information (step ST75). Specifically, as described above, the identification information of the imaging device 15 is registered in an object record R which is assigned to the object selected by the user. For each object, the object record R includes identification information IDq for specifying a wireless communication device 12 which is placed near the object. Furthermore, the control device 13 is able to identify the wireless communication device 12 which has currently transferred the identification information. Thus, based on such information, the area information generation section 134 determines whether the imaging device 15 is located near the object selected by the user. If the object is located near the imaging device 15, the area information generation section 134 determines that area information is to be generated. Otherwise, the area information generation section 134 awaits a next reception of identification information.

After generating area information indicating that the user is located near the selected object, the area information generation section 134 transmits the area information to the wireless communication device 12 which is currently communicating with the imaging device 15, via the communication section 136 (step ST76, sequence SQ76). The wireless communication device 12 transmits the area information which is sent from the control device 13 to the imaging device 15 (sequence SQ77).

The transmission of the aforementioned identification information is to be performed before the imaging device 15 enters the coverage area of each wireless communication device 12. Since the user will freely move around in the place where the system is placed, the wireless communication processing section 1511 establishes a wireless link with a wireless communication device 12 which is placed near the object selected by the user.

In the imaging device 15, upon receiving the area information via the wireless communication section 154, the wireless communication processing section 1511 displays the content represented by the received area information on the displaying section 156 (step ST77). The content represented by the area information may be output as audio, or may be output as vibration. Through step ST77 above, the user is able to recognize that the user is being near the object selected by himself or herself.

In the control device 13, the light emission instructing section 135 passes the selection information and the synchronization signal to the phototransmitter 11 which is assigned to the object record R (i.e., an object) used for generating the area information, and instructs the phototransmitter 11 to transmit invisible light (FIG. 23B; step ST78, sequence SQ78). In response to the instruction from the light emission instructing section 135, the phototransmitter 11 sends out invisible light having the selection information and the synchronization signal superposed thereon (step ST79, sequence SQ79).

If the user brings the imaging device 15 near the object in this state, the photoreceiving section 152 of the imaging device 15 receives the invisible light which is being sent out from the phototransmitter 11 (e.g., 11a) (step ST710). In the processor section 155, the optical communication processing section 159 receives the selection information and the synchronization signal which are on the superposed invisible light received by the photoreceiving section 152, and compares the received selection information against the selection information which is already stored in the storage section 157 to determine whether they match or not (step ST711).

If step ST711 determines YES, the optical communication processing section 159 passes the received synchronization signal to the image processing section 1510, and instructs the image processing section 1510 to take in an image (step ST712). If step ST711 determines NO, the optical communication processing section 159 does not give such an instruction.

In response to the above instruction, the image processing section 1510 temporarily stores the image which is sent from the image input section 153 to the internal frame memory (not shown), and displays the image on the displaying section 156 (step ST713). Moreover, in response to the user's operation, the image processing section 1510 may store the image which is stored in the frame memory to the storage section 157.

Thus, according to the present embodiment, a captured image concerning the object (e.g., the object A) which is indicated in the selection information as desired by the user is automatically displayed on displaying section 156 of the imaging device 15. Since the photoreceiving device of the image input section 153 is sensitive to the invisible light, the displaying section 156 will also display the phototransmitter 11 emitting light, the user can easily locate the object selected by himself or herself.

For example, assume that the user has selected the object tomato A at step ST73. If the user moves around in the place where the system is installed under this assumption, the imaging device 15 will receive area information which is provided from the wireless communication device 12c (see FIG. 17), which is placed near the tomato A, in sequence SQ77. Thereafter, if the user brings the imaging device 15 near the tomato A, the invisible light from the phototransmitter 11a is sent to the imaging device 15. The imaging device 15 takes in an image of such emission by the phototransmitter 11a as well as the tomato A, and displays the image on the displaying section 156. As a result, the use can identify the tomato A.

In the present embodiment, the invisible light in the form of infrared radiation performs three roles: a transmission medium of the synchronization signal, a transmission medium of the selection information, and object identification. Infrared radiation, which is used for control signal transmission and data communications in a remote control or IrDA, for example, is not perceived by the human eyes because it is not visible light. However, since infrared radiation falls within the sensitive range of the photoreceiving device comprised by the imaging device 300, the emission of the phototransmitter 100 can be observed by simply allowing the infrared radiation which has been received by the CCD to be displayed on the image displaying section 307. Since invisible light is used, the emission by the phototransmitter 100 is not visually perceived by anyone other than the user. Thus, people in the surrounding vicinity are less likely to be annoyed thereby.

Moreover, according to the present embodiment, since the present system 1 comprises the wireless communication device 12, the user can easily determine whether the user is located near the object or not.

The features described in the second to fifth embodiments can be easily incorporated into the object identification system 1 according to the present embodiment.

The present embodiment illustrates a case where the imaging device 15 sends selection information representing an object. Alternatively, the imaging device 15 may just send information concerning the user's preferences to the information distribution device 14. In this case, based on the user's preferences, the information distribution device 14 will select an object which is of interest to the user, and cause the phototransmitter 11 which is assigned to the selected object to send out invisible light as described above.

The processing by the imaging device according to each of the above embodiments may be implemented by a computer program which is internal to the imaging device. Each computer program may not only be stored to an internal memory of each imaging device, but may also be distributed in a recorded form on a distribution medium such as a CD-ROM, or distributed through a network such as the Internet.

While the invention has been described in detail, the foregoing description is in all aspects illustrative and not restrictive. It is understood that numerous other modifications and variations can be devised without departing from the scope of the invention.

### INDUSTRIAL APPLICABILITY

The system and method for object identification according to the present invention is to be installed in a shop or an exhibition place where the effect of enabling a user to easily locate an object is needed.

1. An imaging device which, in cooperation with a phototransmitter being placed near at least one object and capable of sending out invisible light having rectilinearity, identifies the object by using a photoreceiving device having a sensitive range including a wavelength of the invisible light,
the invisible light having superposed thereon first information for uniquely identifying the object or the imaging device,
the imaging device comprising:
a storage section operable to store second information for uniquely identifying an object selected by a user or the imaging device itself;
a photoreceiving section operable to receive the invisible light sent out from the phototransmitter, and extract the first information superposed on the received light;
a determination section operable to determine whether or not to take in an image based on the first information sent from the photoreceiving section and the second information stored in the storage section;
an image input section operable to take in an image representing light emission by the phototransmitter and surroundings thereof if the determination section has determined to take in an image; and
a displaying section operable to display the image representing light emission by the phototransmitter and the surroundings thereof which has been taken in by the image input section.

2. The imaging device according to claim 1, wherein,
a synchronization signal for controlling the imaging device is further superposed on the invisible light, and
the image input section stores, in accordance with the synchronization signal, the image which has been taken in to a frame memory.

3. The imaging device according to claim 1, further comprising a communication section operable to transmit the first information for identifying the object selected by the user or the imaging device itself to, via a network, a control device which is placed near the object for controlling the light emission by the phototransmitter,
the control device instructing the phototransmitter to transmit the first information which is sent from the communication section.

4. The imaging device according to claim 1, wherein,
the phototransmitter includes a plurality of light-emitting devices, such that related information concerning the object is output through light emission by some of the plurality of light-emitting devices, and
the displaying section further displays the related information concerning the object.

5. The imaging device according to claim 1, wherein,
related information concerning the object is further superposed on the invisible light,
the photoreceiving section extracts the related information from the invisible light which is sent from the phototransmitter,
the imaging device further comprises an image processing section operable to merge the related information which has been extracted by the photoreceiving section with the image which has been taken in by the image input section, and
the displaying section displays the image having the related information merged therewith by the image processing section.

6. The imaging device according to claim 1, further comprising:
a wireless communication section operable to receive area information from a wireless communication device which is placed near the object for transmitting the area information indicating that the object is near; and
an output section operable to output the area information received by the wireless communication section.

7. An object identification method by which, in cooperation with a phototransmitter being placed near at least one object and capable of sending out invisible light having rectilinearity, an imaging device identifies the object by using a photoreceiving device having a sensitive range including a wavelength of the invisible light,
the invisible light having superposed thereon first information for uniquely identifying the object or the imaging device,
the object identification method comprising:
a storage step of storing second information for uniquely identifying an object selected by a user or the imaging device itself;
a photoreceiving step of receiving the invisible light sent out from the phototransmitter, and extract the first information superposed on the received light;
a determination step of determining whether or not to take in an image based on the first information sent from the photoreceiving step and the second information stored in the storage step;
an image input step of taking in an image representing light emission by the phototransmitter and surroundings thereof if the determination step has determined to take in an image; and
a displaying step of displaying the image representing light emission by the phototransmitter and the surroundings thereof which has been taken in by the image input step.

8. A computer program for use in an imaging device which, in cooperation with a phototransmitter being placed near at least one object and capable of sending out invisible light having rectilinearity, identifies the object by using a photoreceiving device having a sensitive range including a wavelength of the invisible light,
the invisible light having superposed thereon first information for uniquely identifying the object or the imaging device,
the computer program comprising:
a storage step of storing second information for uniquely identifying an object selected by a user or the imaging device itself;
an information acquisition step of extracting the first information superposed on the invisible light sent out from the phototransmitter and received by the imaging device;
a determination step of determining whether or not to take in an image based on the first information extracted in the information acquisition step and the second information stored in the storage step;
an image acquisition step of taking in an image representing light emission by the phototransmitter and surroundings thereof if the determination step has determined to take in an image; and
a transfer step of transferring, to a display section comprised by the imaging device, the image representing light emission by the phototransmitter and the surroundings thereof which has been taken in by the image acquisition step.
